(19) United States
(12) Patent Application Publication
(10) Pub. No.: US 2026/0264263 A1
(43) Pub. Date: Sep. 10, 2026

(54) AUTOMATED CENTER FINDING PROCESS

(71) Applicant: Applied Materials, Inc., Santa Clara, CA (US)

(72) Inventors: Ho Yu, Cupertino, CA (US); Paul Zachary Wirth, Kalispell, MT (US); Adam Cranmer, Leander, TX (US); Mohsin Waqar, Oakland, CA (US)

(21) Appl. No.: 19/073,956

(22) Filed: Mar. 7, 2025

(51) Int. Cl. B25J 13/08; B25J 9/16; H01L 21/68; H01L 21/687

(52) U.S. Cl. CPC B25J 13/088; B25J 9/1692; H10P 72/50; H10P 72/7602

(57) ABSTRACT

A method includes loading an end effector with a substrate and determining robot arm positions corresponding to physical locations on the substrate using a fixed sensor. A center point of the substrate is determined using the physical locations. One or more offset values representing a physical relationship between a calibration point of the end effector and the center point of the substrate are calculated. The substrate on the end effector is repositioned on the end effector based on the one or more offset values.

### BACKGROUND

During substrate processing in semiconductor manufacturing, an etching process is used to create precise patterns on the substrate surface. This process, conducted within a controlled processing chamber, often generates byproducts as a result of chemical reactions between the etching gases and the substrate material. These byproducts, which can be gaseous, liquid, or solid, pose significant challenges to the etching process. For example, these byproducts can be re-deposited onto the substrate surface and can lead to several issues, including but not limited to non-uniform etching.

### BRIEF SUMMARY

Aspects and embodiments of the present disclosure include a method that includes loading an end effector with a substrate and determining a first number of physical locations on the substrate using a fixed sensor. A center point of the substrate is determined using the first number of physical locations. One or more offset values representing a physical relationship between a calibration point of the end effector and the center point of the substrate are calculated. The substrate on the end effector is repositioned on the end effector based on the one or more offset values.

Aspects and embodiments of the present disclosure include a device that has one or more processors. The device also includes a memory storing instructions that, when executed by the one or more processors, cause the device to load an end effector with a substrate and determine a first number of physical locations on the substrate using a fixed sensor. A center point of the substrate is determined using the first number of physical locations. One or more offset values representing a physical relationship between a calibration point of the end effector and the center point of the substrate are calculated. The substrate on the end effector is repositioned on the end effector based on the one or more offset values.

Aspects and embodiments of the present disclosure include a substrate processing system that has a robotic arm with a plurality of links that rotate along one or more rotational axis and an end effector, and one or more through-beam sensors. Each of these through-beam sensors are configured to detect when the robotic arm or a substrate is within their respective the field of view (FOV). The substrate processing system also include one or more processors, and a memory storing instructions that, when executed by the one or more processors, cause the substrate processing system to load the end effector with a substrate and determine a first number of physical locations on the substrate using the one or more through-beam sensors. A center point of the substrate is determined using the first number of physical locations. One or more offset values representing a physical relationship between a calibration point of the end effector and the center point of the substrate are calculated. The substrate on the end effector is repositioned on the end effector based on the one or more offset values.

### BRIEF DESCRIPTION OF THE SEVERAL VIEWS OF THE DRAWINGS

To easily identify the discussion of any particular element or act, the most significant digit or digits in a reference number refer to the figure number in which that element is first introduced.

FIG. 1 illustrates a top, schematic diagram of a processing system, according to one embodiment.

FIG. 2A which illustrates a top plan view of a robot, according to one embodiment.

FIG. 2B illustrates a top plan view of an additional robot, according to one embodiment.

FIG. 3 illustrates a top view of an end effector of a robot, according to one embodiment.

FIG. 4 illustrates a process of determining a calibration point for an unloaded end effector, according to one embodiment.

FIG. 5 illustrates a process of determining a center point of a substrate for an end effector loaded with the substrate, according to one embodiment.

FIG. 6 illustrates a comparison of the estimated calibration point and the estimated center point of the substrate, according to one embodiment.

FIG. 7 is a flowchart illustrating a method of automating a center-finding process of a substrate processing system, according to one embodiment.

FIG. 8 is a flowchart illustrating a method of aligning a center point of a substrate with a calibration point on an end effector, according to one embodiment.

FIG. 9 is a block diagram illustrating a computer system 900, according to certain embodiments.

### DETAILED DESCRIPTION

Technologies related to local center finding (LCF) are described herein. In substrate processing systems, a multi-linkage robot arm is located in the factory interface and transfers content between portions of the substrate processing system, such as enclosure systems, an aligner device, a load lock, and/or the like. A multi-linkage robot is also located in the transfer chamber and transfers content between portions of the substrate processing system, such as processing chambers, load locks, sensors, and/or the like. In electronics manufacturing, it is of value to achieve rapid and precise transfer of product components (e.g., substrates such as wafers). In particular, end effectors of robots are oriented precisely relative to content that the robots transport within the manufacturing system. In some instances, improper orienting results in uneven processing and diminished quality of the substrates as a result of misaligned substrate handoffs. In some instances, improper orientation can even result in damage to content or damage to one or more components of the substrate processing system.

Traditionally, load lock chambers in electronics manufacturing tools can be calibrated using an end effector equipped with a specialized calibration wafer, such as a puck calibration wafer. This process may typically begin by manually loading the calibration wafer onto the end effector. Calibration wafers are typically designed with precise dimensions or embedded sensors to facilitate accurate measurement of the position and alignment of the end effector within the load lock chamber. Once the calibration wafer is positioned, the system conducts a series of movements to verify and adjust the alignment within each load lock connected to the mainframe.

However, the manual loading of calibration wafers presents several drawbacks. One significant issue is the increased risk of contamination. Manual handling introduces particles, oils, or residues from the operator's environment to the wafer surface or the load lock chamber, which can compromise calibration precision or downstream processes. Additionally, manual loading is time-intensive, requiring the operator to physically access and interact with the system, leading to inefficiencies in calibration workflows. These inefficiencies are magnified in high-throughput environments, where minimizing downtime is critical. The reliance on manual loading also limits the scalability of the process, as automated tools cannot easily integrate with this manual step. As a result, these challenges make manual loading of calibration wafers undesirable.

Aspects and embodiments of the present disclosure address the problems and challenges mentioned above and others by providing an automated LCF process that centers a substrate on the end effector without manual intervention. By providing such an automated LCF process, the present disclosure can improve the speed, cleanliness, and consistency of calibration workflows, such as a load lock calibration process. Aspects and embodiments of the present disclosure allow for calibration processes, such as the calibration of sensors within a load lock chamber, to be performed within a vacuum environment. This is because the present disclosure provides an LCF process that does not necessitate a human operator to open a transfer chamber or a load lock to load a puck calibration wafer onto the end effector.

In at least one embodiment, the aspects and embodiments of the present disclosure are not limited to being performed at room temperature. For example, if a silicon or glass substrate is used to perform processes or methods described herein, aspects and embodiments of the present disclosure may be performed at actual chamber process temperatures (e.g., 500+ degrees Celsius) or the temperature of a heated load lock (e.g., 200+ degrees Celsius). At these higher temperatures, thermal expansion of robot linkage, end effector, transfer chamber, sensors, load locks, and/or process chambers may be fully accounted for during calibrations and can result in a higher accuracy of calibration.

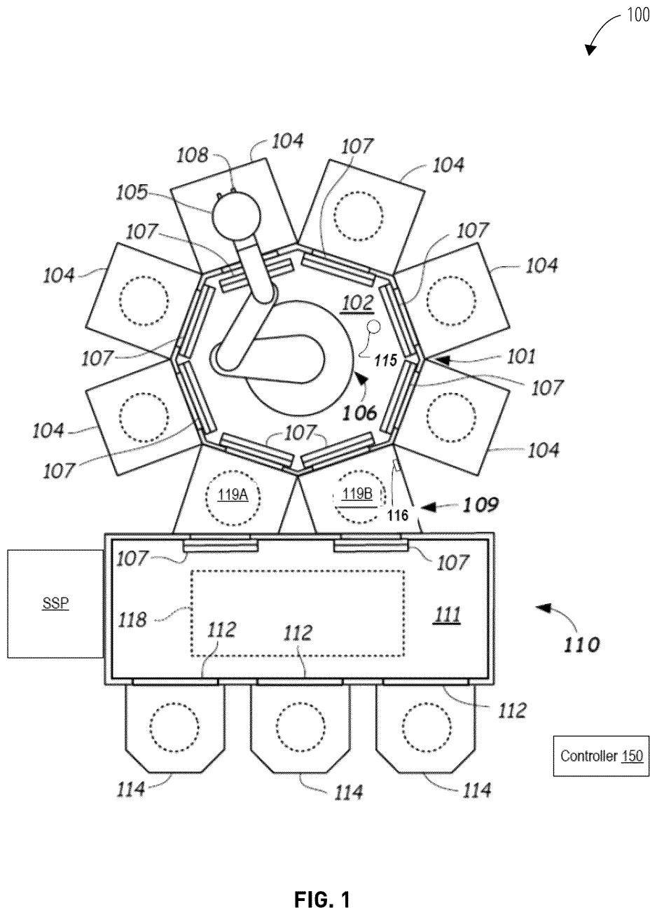

FIG. 1 illustrates a top, schematic diagram of a processing system 100 (e.g., an electronic device processing apparatus, a substrate processing system). The processing system 100 transfers content (e.g., substrates, process kit rings, carriers, validation wafers, components, etc.) between different portions of the processing system 100. The processing system 100 is adapted to process substrates 105 (e.g., 300 mm or 450 mm silicon-containing wafers, silicon plates, or the like) by imparting one or more processes thereto (e.g., via one or more process chambers 104). The processes include degassing, cleaning, pre-cleaning, deposition such as chemical vapor deposition (CVD), physical vapor deposition (PVD), atomic layer deposition, coating, oxidation, nitration, etching, polishing, lithography, and/or the like. In some embodiments, the processing system 100 includes process chambers 104 that include one or more of etch chambers, deposition chambers (including atomic layer deposition, chemical vapor deposition, physical vapor deposition, or plasma enhanced versions thereof), anneal chambers, and/or the like.

The depicted processing system 100 includes a mainframe housing 101 including a transfer chamber 102 formed therein. The transfer chamber 102 is formed by a lid (removed for illustration purposes), a bottom, and side walls, and is maintained at a vacuum in some embodiments, for example. The mainframe housing 101 includes any suitable shape, such as square, rectangular, pentagon, hexagon, heptagon, octagon (as shown), or other geometric shapes. In the depicted embodiment, a robot 106, such as a multi-arm robot (also referred to as a multi-linkage robot), is positioned at least partially inside of the transfer chamber 102. The robot may also be positioned at least partially inside of a process chamber 104. The robot 106 is adapted to be operable therein to service various chambers (e.g., one or more process chambers 104 and/or one or more load lock chambers 109) arranged around the transfer chamber 102. The transfer chamber 102 depicted in FIG. 1 is coupled to six process chambers 104 and two load lock chambers 109. However, other numbers of process chambers 104 and load lock chambers 109 are used in other embodiments.

The robot 106 is adapted to pick and place content, such as substrates 105 (sometimes referred to as “wafers” or “semiconductor wafers”), mounted on the end effector 108 (sometimes referred to as a “blade”) of the robot 106 to or from destinations through one or more slit valve assemblies 107. In the depicted embodiment of FIG. 1, the robot 106 is any suitable multi-arm robot that has sufficient mobility to transfer substrates 105 between the various process chambers 104 and/or the load lock chambers 109.

In the depicted embodiment of FIG. 1, the robot 106 is shown located and housed in a transfer chamber 102. However, it should be recognized that this embodiment of the robot 106, as well as the other robots described herein, are used in other areas of electronic device manufacturing, such as in electronic front end module (EFEM) 110 (e.g., factory interface) where the robot transports content (e.g., substrates 105) between load ports of substrate carriers 114 (e.g., enclosure systems, FOUPs, etc.) and load lock chambers 109, for example. The robot 106 described herein is also capable of other transporting uses.

The load lock chambers 109 are adapted to interface with an interface chamber 111 of the EFEM 110 (also referred to as a factory interface). The EFEM 110 receives content (e.g., substrates 105) from substrate carriers 114, such as front opening unified pods (FOUPs) docked at load ports 112. A robot 118 (load/unload robot, factory interface robot, atmospheric robot, EFEM robot, etc.) (shown dotted) is used to transfer substrates 105 between the substrate carriers 114 and the load lock chambers 109. In some embodiments, the robot 118 has the same or similar components (e.g., end effector 108, etc.) and functionalities as the robot 106. Slit valve assemblies 107 are provided at some or all of the openings into the process chambers 104 and also at some or all of the openings of the load lock chambers 109.

Robot 118 includes a robot arm, such as a selective compliance assembly robot arm (SCARA) robot. Examples of a SCARA robot include a 2 link SCARA robot, a 3 link SCARA robot, a 4 link SCARA robot, and so on. The robot 118 includes an end effector 108 on an end of the robot arm. The end effector 108 is configured to pick up and handle specific objects, such as substrates. Alternatively, or additionally, the end effector 108 is configured to handle objects such as a calibration substrate, process kit rings (edge rings), and/or substrates. The robot 118 has one or more links or members (e.g., wrist member, upper arm member, forearm member, etc.) that are configured to be moved to move the end effector 108 in different orientations and to different locations. The illustrated robot 118 includes a single end effector. However, it should be understood that the robot 118 may have any number of end effectors (e.g., 2 end effectors, 3 end effectors, 4 end effectors, 5 end effectors, etc.). In some embodiments, each of the end effectors is part of a distinct link (e.g., wrist member), where each of the wrist members are attached to the same link (e.g., to the same upper arm or forearm), and optionally at a same rotational axis. Alternatively, different end effectors may be parts of links (e.g., wrist members) that are attached to different links (e.g., to different upper arms or forearms). For example, a robot may include a single upper arm, 2 forearms, and a wrist member (and associated end effector) attached to each of the forearms. In another example, a robot may include a single upper arm, 2 forearms, and two wrist members (and associated end effectors) attached to each of the forearms. In another example, a robot may include two upper arms, a forearm attached to each of the upper arms, and one or more wrist members (and associated end effector) attached to each of the forearms.

In embodiments, one or more joints or links of the robot include one or more sensors used to determine positions of the links. The sensors of the links/joints may include optical encoders in embodiments. The optical encoders may be used to generate joint position measurements, which may be used for servo feedback control of the links.

The robot 118 is configured to transfer objects between substrate carriers 114 (e.g., cassettes, FOUPs) (or load ports), load locks 119A, 119B, SSP, aligner device, and/or the like. While conventional systems are associated with opening of (e.g., disassembly of, breaking the seal of, contaminating, etc.) a processing system (e.g., EFEM) by an operator to determine error values and perform corrective actions for (e.g., teach, calibrate, and/or diagnose malfunctioning of) a robot (e.g., of factory interface robot), the processing system 100 is configured to facilitate determining of error values and performing of corrective actions (e.g., automatic teaching, calibrating, and/or diagnosis) without opening of (e.g., disassembly of, breaking the seal of, contaminating, etc.) the processing system 100 by an operator. Accordingly, in embodiments a sealed environment including an interior volume of a transfer chamber 102 and/or an internal volume of the EFEM 110 are maintained during calibration or recalibration of robots. Embodiments are discussed with reference to calibrating robot 106 in transfer chamber 102. However, it should be understood that similar techniques may also be applied to calibrate robot 118 of EFEM 110. Accordingly, any discussion of calibration of a transfer chamber robot herein equally applies to calibration of an EFEM robot.

In some embodiments, the robot 106 is substantially similar to the robot 118. In some embodiments, the robot 106 is a SCARA robot, but has fewer links and/or fewer degrees of freedom than the robot 118.

Content, such as substrates 105, are received into the transfer chamber 102 from the EFEM 110 and also exit the transfer chamber 102, to the EFEM 110, through the load lock chambers 109 that are coupled to a surface (e.g., a rear wall) of the EFEM 110. The load lock chambers 109 include one or more load locks (e.g., load locks 119A, 119B, for example). In some embodiments, load locks 119A, 119B that are included in the load lock chambers 109 are single wafer load lock (SWLL) chambers, multi-wafer chambers, or combinations thereof, for example. Each of the substrate carriers 114 are located on a load port. In some embodiments, the load ports are directly mounted to (e.g., sealed against) the EFEM 110. Substrate carriers 114 (e.g., cassette, FOUP, process kit enclosure system, enclosure system, or the like) are configured to removably couple (e.g., dock) to the load ports. In some embodiments, one or more substrate carriers 114 are coupled to the load ports for transferring wafers and/or other substrates into and out of the processing system 100. Each of the substrate carriers 114 seal against a respective load port. In some embodiments, a first substrate carrier 114 is docked to a first load port.

In some embodiments, a load port includes a front interface that forms a vertical opening (or a substantially vertical opening). The load port additionally includes a horizontal surface for supporting a substrate carrier 114 (e.g., cassette, enclosure system, FOUP, etc.). Each substrate carrier 114 (e.g., FOUP of wafers, process kit enclosure system) has a front interface that forms a vertical opening. The front interface of the substrate carrier 114 is sized to interface with (e.g., seal to) the front interface of the load port (e.g., the vertical opening of the substrate carrier 114 is approximately the same size as the vertical opening of the load port). The substrate carrier 114 is placed on the horizontal surface of the load port and the vertical opening of the substrate carrier 114 aligns with the vertical opening of the load port. The front interface of the substrate carrier 114 interconnects with (e.g., is clamped to, is secured to, is sealed to) the front interface of the load port. A bottom plate (e.g., base plate) of the substrate carrier 114 has features (e.g., load features, such as recesses or receptacles, that engage with load port kinematic pin features, a load port feature for pin clearance, and/or an enclosure system docking tray latch clamping feature) that engage with the horizontal surface of the load port. The same load ports are used for different types of substrate carriers 114 (e.g., FOUP, process kit enclosure system, cassettes that contain wafers, etc.).

In some embodiments, the processing system 100 also includes first vacuum ports (e.g., slit valve assemblies 107 between the load locks 119 and the EFEM 110) coupling the EFEM 110 to respective load locks 119 (e.g., degassing chambers). Second vacuum ports (e.g., slit valve assemblies 107 between the load locks 119 and the transfer chamber 102) are coupled to respective load locks 119 (e.g., degassing chambers) and are disposed between the load locks 119 and transfer chamber 102 to facilitate transfer of substrates 105 and content (e.g., process kit rings, calibration disc, etc.) into the transfer chamber 102. In some embodiments, processing system 100 includes and/or uses one or more load locks 119 and a corresponding number of vacuum ports (e.g., slit valve assemblies 107) (e.g., a processing system 100 includes a single load lock 119, a single first slit valve assembly 107, and a single second slit valve assembly 107).

The transfer chamber 102 includes process chambers 104 (e.g., four process chambers 104, six process chambers 104, etc.) disposed therearound and coupled thereto. The process chambers 104 are coupled to the transfer chamber 102 through respective ports 107, such as slit valves or the like.

In some embodiments, the EFEM 110 is at a higher pressure (e.g., atmospheric pressure) and the transfer chamber 102 is at a lower pressure (e.g., vacuum). Each load lock 119 (e.g., degassing chamber, pressure chamber) has a first door (e.g., first slit valve assembly 107) to seal the load lock 119 from the EFEM 110 and a second door (e.g., second slit valve assembly 107) to seal the load lock 119 from the transfer chamber 102. Content is to be transferred from the EFEM 110 into a load lock 119 while the first door is open and the second door is closed, the first door is to close, the pressure in the load lock 119 is to be reduced to match the transfer chamber 102, the second door is to open, and the content is to be transferred out of the load lock 119. An LCF device is to be used to align the content in the transfer chamber 102 (e.g., before entering a process chamber 104, after leaving the process chamber 104).

A controller 150 controls various aspects of the processing system 100. The controller 150 is and/or includes a computing device such as a personal computer, a server computer, a programmable logic controller (PLC), a microcontroller, and so on. The controller 150 includes one or more processing devices, which, in some embodiments, are general-purpose processing devices such as a microprocessor, central processing unit, or the like. More particularly, in some embodiments, the processing device is a complex instruction set computing (CISC) microprocessor, reduced instruction set computing (RISC) microprocessor, very long instruction word (VLIW) microprocessor, or a processor implementing other instruction sets or processors implementing a combination of instruction sets. In some embodiments, the processing device is one or more special-purpose processing devices such as an application specific integrated circuit (ASIC), a field programmable gate array (FPGA), a digital signal processor (DSP), network processor, or the like. In some embodiments, the controller 150 includes a data storage device (e.g., one or more disk drives and/or solid state drives), a main memory, a static memory, a network interface, and/or other components. In some embodiments, the controller 150 executes instructions to perform any one or more of the methods or processes described herein. The instructions are stored on a computer readable storage medium, which include one or more of the main memory, static memory, secondary storage and/or processing device (during execution of the instructions). The controller 150 receives signals from and sends controls to robot 118 and robot 106 in some embodiments.

One or more sensors within the processing system 100 allow for determining error values and performing corrective actions (e.g., teaching, calibrating, and/or diagnosing) of one or more links and/or end effectors or robot 106 and/or robot 118 of the processing system 100 without opening the sealed environment within the EFEM 110 and/or transfer chamber 102 and/or adjacent chambers. In embodiments, the one or more sensors include a vertically oriented sensor 115 in transfer chamber 102. In some embodiments, the one or more sensors include a horizontally oriented sensor 116 in one or more load locks 119A-B. In some embodiments, the one or more sensors include a vertically oriented sensor within the interface chamber 111 or the transfer chamber 102. The one or more sensors may be located within the transfer chamber 102, the process chamber 104, a pass thru chamber, and/or the load lock 116. In some embodiments, sensor 115 and/or sensor 116 includes an emitter and a detector. The sensor may be, for example, a through-beam optical sensor. The through-beam optical sensor may include one or more fiber optic cables to direct a beam of light output by the emitter to a target location in embodiments. Additionally, or alternatively, the through-beam optical sensor may include one or more fiber optic cables to receive the beam of light output by the emitter and to direct the beam of light to the detector. In some embodiments, the emitter may be, for example, a laser emitter that outputs a laser beam. In other embodiments, the emitter may be or include a light-emitting diode (LED) driver and/or amplifier. The detector may include an optical detector such as one or more photodiode, a complementary metal oxide semiconductor (CMOS) sensor, a charge coupled device (CCD) sensor, and so on. In some embodiments, the detector may receive the light output of the emitter, and depending on whether or not the light output is received by the detector a presence of an object in the field of view of the sensor may be determined. For example, in some embodiments the detector may ordinarily receive the light output, and when the light output is not received, a determination can be made that an object is interposed between the emitter and detector (or between a combined emitter/detector and a reflector that ordinarily reflects the light output (e.g. laser beam) from the laser back to the detector). In some embodiments, an object is detected when the detector receives the light output. For example, an object to be detected may include a reflector on the object, which may reflect the light output by the emitter to the detector when the object is placed in the field of view of the sensor.

In embodiments, controller 150 may cause robot 106 to move one or more links of the robot through one or a series of predefined motions (e.g., between a series of predefined positions). Moving the links through the series of predefined motions may cause the link(s) of the robot arm to pass through the field of view of the vertical sensor 115. Controller 150 may record robot link positions at which the one or more links are detected by the vertical sensor 115, and based on this information may determine a zero position for each of the links and ultimately calibrate the robot 106 within transfer chamber 102. This process may be performed periodically to make sure that the robot maintains calibration, to detect drift of any of the links of the robot, and so on. Similarly, controller 150 may cause one or more end effectors of robot 106 to extend into load lock 116 and move vertically across a field of view of horizontal sensor 116. Controller 150 may record robot vertical positions at which one or more extended end effectors are detected and may determine zero vertical positions of the end effector(s) based on the detected vertical positions. In this manner, controller 150 may perform automatic horizontal calibration or robot links and vertical calibration of end effectors of robot 106. A similar process may be performed for robot links and/or end effectors of robot 118 of EFEM 110 in embodiments.

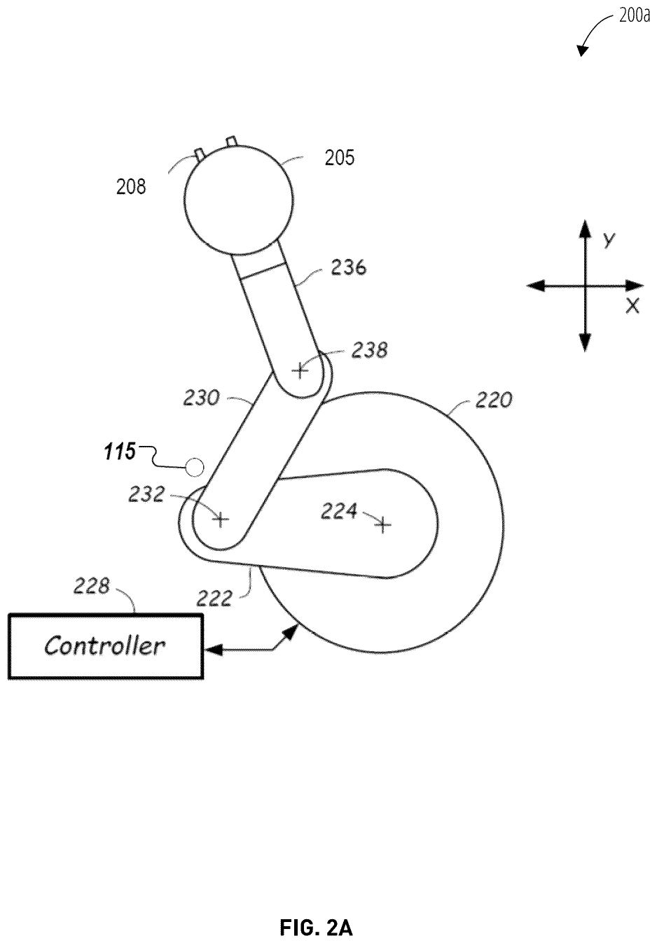

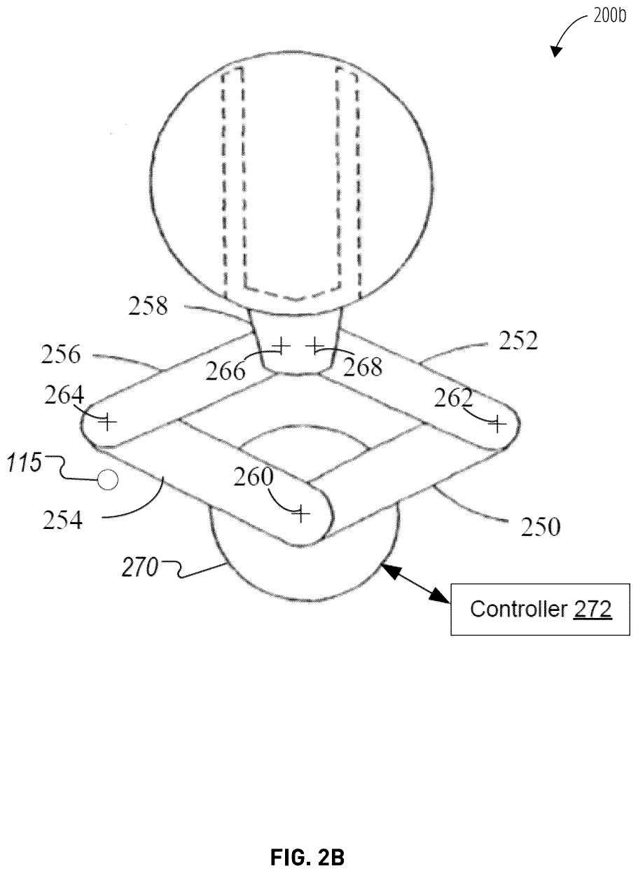

Reference is made to FIG. 2A, which illustrates a top plan view of a robot 200a (e.g., robot 106 and/or robot 118 of FIG. 1), according to certain embodiments. Reference is also made to FIG. 2B, which illustrates a cross-sectioned side view of a robot 200a (e.g., robot 106 and/or robot 118 of FIG. 1), according to certain embodiments. In the illustrated example, the links includes sides having a straight edge profile. In other examples, link side wall may not be a straight edge as depicted in the figures and it may have curvature, a convex feature and/or a concave feature. Link shapes may be complex and may or may not have special purpose protruding features with strict tolerances intended for accurately locating the joint position of the link. A link may contain recesses or cavities such as a thru hole within the link, or an imprinted surface feature such as a fiducial that is easily recognized by an imaging sensor, for example. These special purpose features may be used to accurately locate a centerline of the link.

In some embodiments, the robot 200a includes a base 220 adapted to be attached to a wall or floor of the processing system. In some embodiments, the robot 200a also includes a first link 222 (e.g., an upper arm), which, in the depicted embodiments, is a substantially rigid cantilever beam. The first link 222 is adapted to be rotated about a first rotational axis 224 in clockwise and counterclockwise rotational directions. The rotation about first rotational axis 224 is provided by any suitable motor, such as a variable reluctance or permanent magnet electric motor. The motor is received in a motor housing 226. The rotation of the first link 222 is controlled by suitable commands to the motor from a controller 228.

A second link 230 (e.g., a forearm) is coupled to the first link 222 at a second rotational axis 232. The second rotational axis 232 is spaced from the first rotational axis 224. The second link 230 is adapted for rotation in the X-Y plane relative to the first link 222 about the second rotational axis 232. A third link 236 (e.g., a wrist member) is coupled to the second link 230 at a third rotational axis 238. The third link 236 is adapted for rotation in the X-Y plane about the third rotational axis 238. The end effector 208 is coupled to the third link 236 and is adapted to carry and transport a substrate 205. While only a single third link (e.g., wrist member) 236 is shown connected to the second link, in embodiments, multiple different wrist members (e.g., a fourth link, a fifth link, etc.) may additionally be connected to the second link. Each of the wrist members may be separately rotatable about the third rotational axis 238. Additionally, it should be understood that embodiments described herein with reference to a robot arm including three links (e.g., an upper arm, forearm, and one or more wrist members) also apply to robot arms that include different numbers of links. For example, some robot arms may include a fourth link that is rotatable about a fourth rotational axis that connects the fourth link to the third link. Alternatively, the robot arm may not include a third link, and second link may include an end effector.

FIG. 2B illustrates a top plan view of an additional robot 200b, according to embodiments of the present disclosure. In embodiments, robot 200b is a parallel arm robot having multiple arms or links that couple to a same end effector, also referred to as a “frog leg” robot. In the illustrated example, the links include sides having a straight edge profile. In other examples, link side walls may not be a straight edge as depicted in the figures and may have curvature, a convex feature and/or a concave feature. Link shapes may be complex and may or may not have special purpose protruding features with strict tolerances intended for accurately locating the joint position of the link. A link may contain recesses or cavities such as a thru hole within the link, or an imprinted surface feature such as a fiducial that is easily recognized by an imaging sensor, for example. These special purpose features may be used to accurately locate a centerline of the link.

In some embodiments, the robot 200b includes a base 270 adapted to be attached to a wall or floor of the processing system. In some embodiments, the robot 200b also includes a first link 250 (e.g., a first upper arm) and a second link 254 (e.g., a second upper arm). The first link 250 is adapted to be rotated about a first rotational axis 260 in clockwise and counterclockwise rotational directions. Similarly, the second link 254 is adapted to be rotated about first rotational axis 260 in clockwise and counterclockwise rotational directions. In some embodiments, first link and second link may rotate about different rotational axes. The rotation of first link 250 about first rotational axis 260 is provided by a first motor, and the rotation of second link 254 about first rotational axis 260 is provided by a second motor. The rotation of the first link 250 and of the second link are controlled by suitable commands to the motor from a controller 272, which may correspond to controller 150 of FIG. 1 in some embodiments.

A third link 252 (e.g., a first forearm) is coupled to the first link 250 at a second rotational axis 262. Similarly, a fourth link 256 (e.g., a second forearm) is coupled to the second link 254 at a third rotational axis 264. The second rotational axis 262 and third rotational axis 264 are spaced from the first rotational axis 260 and from each other. The third link 252 is adapted for rotation in the X-Y plane relative to the first link 250 about the second rotational axis 262, and the fourth link 256 is adapted for rotation in the X-Y plane relative to the second link 254 about the third rotational axis 264.

A fifth link 258 (e.g., a wrist member) may be coupled to the third link 252 at a fourth rotational axis 268 and to the fourth link 256 at a fifth rotational axis 266. Alternatively, the fifth link 258 may be coupled to the third link 252 and to the fourth link at a same rotational axis. In some embodiments, third link 252 and fourth link 256 are not associated with their own motors, and are instead automatically moved responsive to movement of first link 250 and/or a second link 254. Similarly, fifth link 258 may not be associated with its own motor, and may instead automatically be moved responsive to movement of the third link 252 and fourth link 256, caused by the movement of the first link 250 and/or a second link 254.

Fifth link 258 may include an end effector, which may extend or retract based on controlled rotation of first link 250 and/or second link 254. In embodiments, rotation of first link 250 and second link 254 in a same direction and amount causes the relation between the first link 250 and second link 254 to remain unchanged, which causes all of the links to rotate together, and for the fifth link 258 to remain at a same radial distance from rotational axis 260. Rotation of first link 250 and second link 254 towards each other causes the fifth link 258 and attached end effector to extend, and rotation of the first link 250 and second link 254 away from each other causes the fifth link 258 and attached end effector to retract.

It should be understood that embodiments described herein with reference to robot 200b also apply to robot arms that include different numbers of links and/or end effectors. For example, some robot arms may include one or more additional pairs of parallel links that together control extraction and retraction of one or more additional end effectors. For example, a sixth link may be connected to first link 250 at a sixth rotational axis near second rotational axis 262, and a seventh link may be connected to second link 254 at a seventh rotational axis near third rotational axis 264. An eighth link that includes an additional end effector may then be connected to both the sixth and seventh links at one or more additional rotational axes. In some embodiments, the eighth link is directed 180 degrees from fifth link 258, and an end effector of the eighth link points directly opposite the end effector of fifth link 258. In another example, fifth link 258 may include multiple end effectors (e.g., two or more parallel end effectors) attached thereto, which may extend and retract in unison in embodiments.

In embodiments, one or more of the links and/or the end effector of robot 200b may be calibrated (e.g., horizontal zero positions of the links and/or end effector may be determined) in the same manner as described herein with reference to robot 200a. For example, first link 250 may be rotated such that it passes through a field of view of vertically-oriented sensor 115 to determine a zero horizontal position of the first link 250. Similarly, second link 254 may be rotated such that it passes through the field of view of vertically-oriented sensor 115 to determine a zero horizontal position of the second link 254. In some embodiments, first and second links 250, 254 are rotated together (e.g., both rotated clockwise and/or counterclockwise) to move the first link 250 and/or second link 254 through the field of view of the sensor 115. Alternatively, first link 250 may be moved without also moving second link 254 and/or the second link 254 may be moved without also moving the first link 250 to generate measurements of first link 250. In some embodiments, first link 250 and second link 254 are moved together to cause a link to be measured to be positioned near sensor 115. Once the link to be measured is in position, then that link may be rotated without also rotating the other link. This would cause the relative position of the link being measured to change with respect to the link not being measured, which would in turn cause the end effector and fifth link 258 to extend or retract during measurement of the first or second link. Once zero horizontal positions of the first and second link are determined, the zero positions for the third and/or fourth links may be determined. This may include moving both the first and second links in such a manner to cause third link 252 to pass through the field of view of the sensor 115, and similarly moving both the first and second links in such a manner to cause fourth link 256 to pass through the field of view of the sensor 115. Similarly, the zero horizontal position of fifth link 258 and/or its end effector may be determined by moving both the first and second links in such a manner to cause fifth link 258 and/or its end effector to pass through the field of view of the sensor 115. In some embodiments, the zero horizontal position of fifth link 258 may be determined without first determining the zero horizontal positions of third and/or fourth links.

In some embodiments, the zero horizontal position of the fifth link 258 may be determined without first determining the zero horizontal positions of any of the first through fourth links. For example, along the centerline of the end effector, the robot may rotate the first and/or second links to extend and retract the end effector to find a center hole of the end effector. Similarly, the first and/or second links may be rotated (e.g., rotated together) to cause the end effector to rotate about rotational axis 260 while maintaining a same radial distance from the rotational axis 260. Points along the edges of the center hole may be used to fit a circle and find the center of the hole. The zero position of the robot may be established by the found center point of the end effector. This process may also be performed after finding the zero positions for any of the first through fourth links. Accordingly, in some embodiments the end effector is used for establishing the zero horizontal position of robot without determining zero horizontal positions of other links of the robot, while in other embodiments the end effector is used to establish the zero horizontal position of the fifth link after finding the zero horizontal positions of other links.

Any discussion herein with reference to determining zero horizontal positions of links and/or of calibrating robots can also apply to parallel arm robots, such as the parallel arm robot 200b of FIG. 2B.

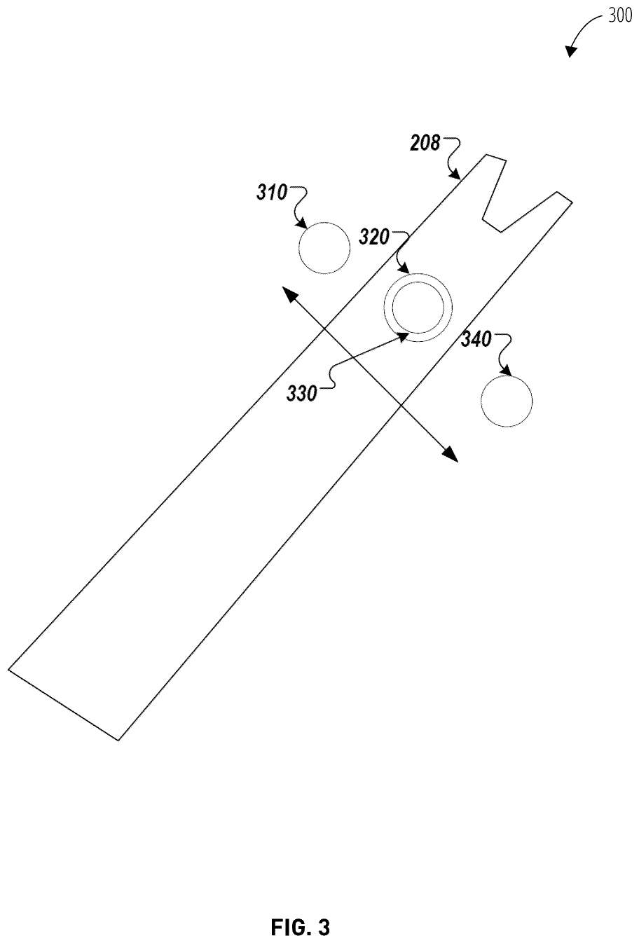

FIG. 3 illustrates a top view 300 of an end effector 208 of robot 200a, according to embodiments of the present disclosure. In some embodiments, the end effector 208 may include a hole 320 at the center of the body of the end effector along a transverse axis of the end effector (centered between the left and right edges of the end effector) that allows for the beam of a sensor to pass through at the center of the end effector 208. In some embodiments, the position of the center of the end effector 208 is determined by the detection of the hole 320 of the end effector 208 as the end effector 208 passes between at least two stations (310, 340) and through a field of view of a sensor 330. As the end effector 208 progresses through a field of view (FOV) of the sensor 330, an initial measurement of the position of the center of the end effector 208 via the hole 320 may be determined, and the position of the end effector 208 (e.g. blade) may be fully validated. In embodiments, a link position for the left and right sidewall of the hole may be determined, which may be used to compute a link position that would place center of the end effector under the field of view (FOV) of the sensor. Additionally or alternatively, the end effector (which may correspond to a link of the robot arm) may be detected by detecting a left and/or right outer edge of the end effector 208 using the sensor. However, the end effector 208 may be capable of moving any direction in a two-dimensional plane substantially orthogonal to the direction of the FOV of the sensor. As such, the end effector 208 may move any direction along this plane in order to determine measurements of the side walls of the hole 320 in the center of the end effector 208. In at least some embodiments, it is acceptable to have at least three separate edge detections on different portions of the side walls of the hole 320.

In embodiments, other tolerance features may also be included in the end effector or other link (e.g., in addition to or instead of holes). Examples of such other tolerance features include recessed features, protruding features, and fiducial marks, which may be formed on any portion of a link or end effector (e.g., on a side of a link, on a top surface of a link, within a body of a link, and so on. In some embodiments, the tolerance feature(s) may be manufactured to a greater accuracy than other portions of a link. This may enable a link zero horizontal position to be determined with increased accuracy based on using detection of the tolerance feature(s) to determine a zero horizontal position for a link. In some embodiments, the position of the link is determined by the detection of a tolerance feature of a link as the link passes between at least two stations and through a field of view of a sensor, using the techniques described above.

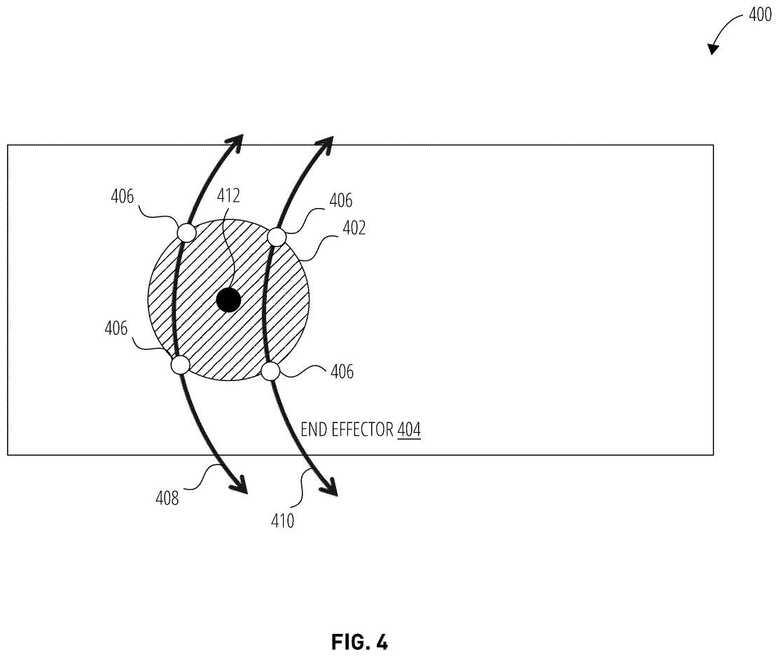

FIG. 4 illustrates a process of determining a calibration point 412 for an unloaded end effector 400, according to one embodiment. In some embodiments, this calibration point 412 may correspond to a zero horizontal position of an end effector 404. As illustrated, the calibration point 412 may be a center of a hole 402 formed by the end effector 404, such as the hole 320 described above with respect to FIG. 3.

According to embodiments, the end effector 404 may move along multiple different paths within an FOV of a sensor, such as a through-beam sensor. As described above with respect to FIG. 3, the end effector 404 may pass through the FOV of the through-beam sensor such that, for each pass, at least two reference points 406 may be determined that correspond to sidewall(s) of the hole 402. These passes may be in any direction substantially orthogonal to the FOV of the sensor. Each reference point 406 may be a different physical location corresponding to a sidewall of the hole 402. If at least two passes are performed, four or more reference points 406 may be determined that each correspond to sidewall(s) of the hole 402. For example, as illustrated, a first pass 408 may determine a first reference point 406 and a second reference point 406, while a second pass 410 may determine a third reference point 406 and a fourth reference point 406. These reference points 406 may be determined based on an output of the through-beam sensor. For example, for each pass, the through-beam sensor may initially be unblocked until the unloaded end effector 400 blocks the through-beam sensor. Once the hole 402 passes over the through-beam sensor, the through-beam sensor may become unblocked. This may correspond to a first reference point 406 of this pass. Then, once the hole 402 concludes its pass over the through-beam sensor, the through-beam sensor may again become blocked. This may correspond to a second reference point 406 of this pass. These reference points 406 may be used to estimate the position of the calibration point 412, which in the illustrated embodiment, is the center of the hole 402.

Each time the through-beam sensor transitions from blocked to unblocked or from unblocked to blocked, it indicates that a defined boundary of the unloaded end effector 404, such as an external edge or the sidewall of the hole 402, has passed through the field of view (FOV) of the sensor (i.e., the path of the through-beam sensor). At the moment this transition occurs, the robot arm is in a specific position defined by its joint angles or actuator positions (which may be referred to as the robot's arm settings or parameters). This correspondence between a sensor transition and the robot arm position at that moment allows linking of a known geometric feature on the end effector, such as a sidewall of the hole 402, to the robot arm position at the moment that the sensor transitions.

By determining the robot arm position at transition events of the sensor, a spatial relationship between these transitions and the hole 402 can be effectively captured. Since the through-beam sensor is fixed in a known location relative to the robot arm, the robot arm parameters at the moment that the sensor transitions between blocked and unblocked states may be translated into a two-dimensional coordinate space. Each of the reference points 406 mentioned above may be determined by translating the robot arm position at the moment that the sensor transitions between blocked and unblocked states. In some embodiments, each of the reference points 406 may correspond to different coordinates, which correspond to a portion of a sidewall of the hole 402.

In various embodiments, the first and second passes 408, 410 may be performed by swinging or otherwise moving the end effector 404 about a rotational axis, such as any of the rotational axis described above with respect to FIG. 1, FIG. 2A, or FIG. 2B. In other embodiments, the first and second passes 408, 410 may be performed by moving the unloaded end effector 400 along a straight path.

Once these reference points 406 are determined or otherwise identified, the calibration point 412 may be estimated. To determine the calibration point 412, which here is the center of the hole 402, one may use any conventional formula or algorithm to find the center of a circle. According to embodiments, these conventional formulas may require that at least three reference points 406 be determined that correspond to points located along the edge of the circle (i.e., the sidewall(s) of the hole 402). In one embodiment, given that the reference points 406 on the circumference are equidistant from the calibration point 412, straight lines (chords) connecting pairs of these reference points 406 are identified, and then perpendicular bisectors of these chords are constructed. Because the center of a circle lies at the same distance from every point on the circumference, the calibration point 412 is positioned where these perpendicular bisectors intersect.

If the radius of the circle (i.e., radius of the hole 402) is known and at least three reference points 406 have been identified as described above, the calibration point 412 may be determined by considering each reference point 406 as a “center” for a radius-based search area. For each of the three or more reference points 406, an imaginary circle may be determined with the given radius with the respective reference point 406 as the center of the imaginary center. Since the calibration point 412 is exactly one radius away from every point on its edge, the calibration point 412 is located at a position that satisfies this condition for all three or more reference points 406 concurrently.

According to embodiments, the through-beam sensor used to determine the reference points 406 may be fixed in any location of a mainframe reachable by the end effector 404 that would allow the end effector 404 to perform passes as described herein. For example, the through-beam sensor may be within the transfer chamber 102, the load lock 119 (119A or 119B), one of the process chambers 104, or the like.

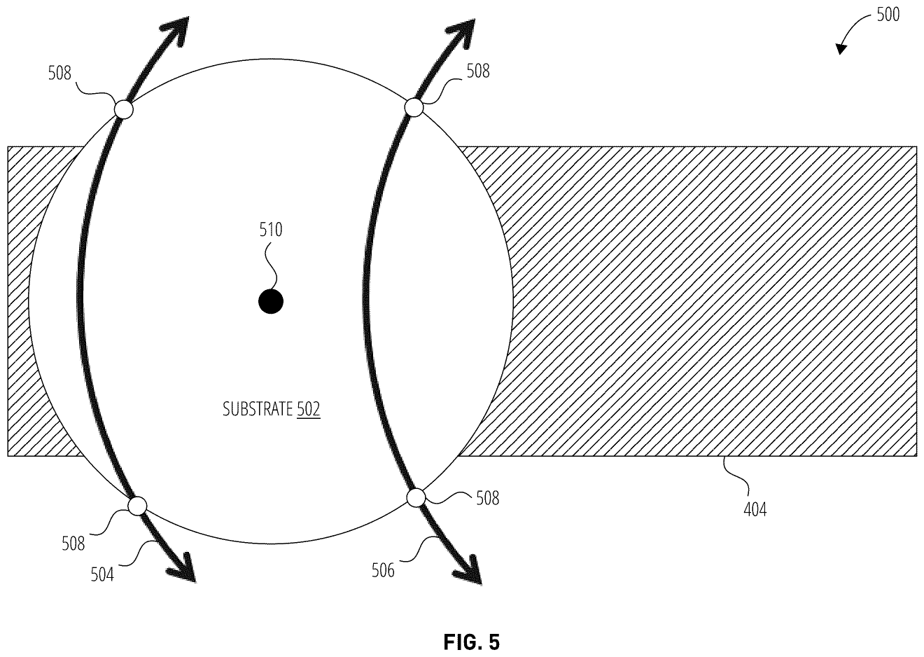

FIG. 5 illustrates a process of determining a center point 510 of a substrate 502 for a loaded end effector 500, according to one embodiment. According to embodiments, the loaded end effector 500 may be the end effector 404 with a loaded substrate 502. The substrate 502 may be a test substrate or a standard production substrate. In at least one embodiment, the substrate 502 is not a special purpose calibration wafer (i.e., not specifically manufactured for the processes or methods described herein). The substrate may be composed of one or more of silicon, glass, bonded substrates, or a variety of substrates. Similar to what is described in FIG. 3 and FIG. 4, multiple reference points 508 may be determined using a sensor, such as a through-beam sensor. Each of these reference points 508 may correspond to a different physical location on an edge of the substrate 502. According to embodiments, the substrate 502 may be circular.

In various embodiments, the loaded end effector 500 may move along multiple different paths within an FOV of a sensor, such as a through-beam sensor. The loaded end effector 500 may pass through the FOV of the through-beam sensor such that, for each pass, at least two reference points 508 may be determined that correspond to an edge of the substrate 502. Each reference point 406 may be a different physical location corresponding to the edge of the substrate 502. If at least two passes are performed, four or more reference points 508 may be determined that each correspond to a different physical location on the edge of the substrate 502. For example, as illustrated, a first pass 504 may determine a first reference point 508 and a second reference point 508, while a second pass 506 may determine a third reference point 508 and a fourth reference point 508. These reference points 406 may be determined based on an output of the through-beam sensor. For example, for each pass, the through-beam sensor may initially be unblocked until the substrate 502 blocks the through-beam sensor. This first change (i.e., unblocked to blocked) may correspond to a first reference point 508 of this pass. Then, the through-beam sensor may become unblocked by the substrate 502. This second change (i.e., blocked to unblocked) may correspond to a second reference point 508 of this pass. These reference points 508 may be used to estimate the center point 510 of the substrate 502.

Each time the through-beam sensor transitions from blocked to unblocked or from unblocked to blocked, it indicates that a defined boundary of the loaded end effector 500, such as an edge of the substrate 502, has passed through the field of view (FOV) of the sensor (i.e., the path of the through-beam sensor). At the moment this transition occurs, the robot arm is in a specific position defined by its joint angles or actuator positions (which may be referred to as the robot's arm settings or parameters). This correspondence between a sensor transition and robot arm position at that moment allows linking of a known geometric feature of the substrate 502, such as the edge of the substrate, to the robot arm position at the moment that the sensor transitions.

By determining the robot arm position at transition events of the sensor, a spatial relationship between these sensor transitions and the substrate 502 can be effectively captured. Since the through-beam sensor is fixed in a known location relative to the robot arm, the robot arm position at the moment that the sensor transitions between blocked and unblocked states may be translated into a two-dimensional coordinate space. Each of the reference points 508 mentioned above may be determined by translating the robot arm position at the moment that the sensor transitions between blocked and unblocked states. In some embodiments, each of the reference points 508 may correspond to different coordinates, which correspond to a portion of an edge of the substrate 502.

In various embodiments, the first and second passes 504, 506 may be performed by swinging or otherwise moving the loaded end effector 500 about a rotational axis, such as any of the rotational axis described above with respect to FIG. 1, FIG. 2A, or FIG. 2B. In other embodiments, the first and second passes 408, 410 may be performed by moving the loaded end effector 500 along a straight path. These first and second passes 504, 506 may be performed in any direction that is substantially orthogonal to the FOV of the sensor.

According to embodiments, any reference point 508 that corresponds to an alignment notch of the loaded wafer 502 may be disregarded. This may help to optimize the ability to calculate the center of the wafer 502. A reference point 508 that corresponds to an alignment notch of the loaded wafer 502 could be identified as not fitting on a same circular fit as the remaining reference points 508.

Once these reference points 508 are determined or otherwise identified, the center point 510 of the substrate 502 may be estimated. To determine the center point 510, any conventional formula or algorithm to find the center of a circle may be used. According to embodiments, these conventional formulas may require that at least three reference points 508 be determined that correspond to points located along the edge of the circle (i.e., the edge of the substrate 502). In one embodiment, given that the reference points 508 on the circumference are equidistant from the center point 510, straight lines (chords) connecting pairs of these reference points 508 are identified, and then perpendicular bisectors of these chords are constructed. Because the center of a circle lies at the same distance from every point on the circumference, the center point 510 is positioned where these perpendicular bisectors intersect.

If the radius of the substrate 502 is known and at least three reference points 508 have been identified as described above, the center point 510 may be determined by considering each reference point 508 as a “center” for a radius-based search area. For each of the three or more reference points 508, an imaginary circle may be determined with the given radius with the respective reference point 508 as the center of the imaginary center. Since the center point 510 is exactly one radius away from every point on its edge, the center point 510 is located at a position that satisfies this condition for all three or more reference points 508 concurrently.

According to embodiments, the through-beam sensor used to determine the reference points reference point 508 may be fixed in any location of a mainframe reachable by the loaded end effector 500 that would allow the loaded end effector 500 to perform passes as described herein. For example, the through-beam sensor may be within the transfer chamber 102, the load lock 119 (119A or 119B), one of the process chambers 104, or the like.

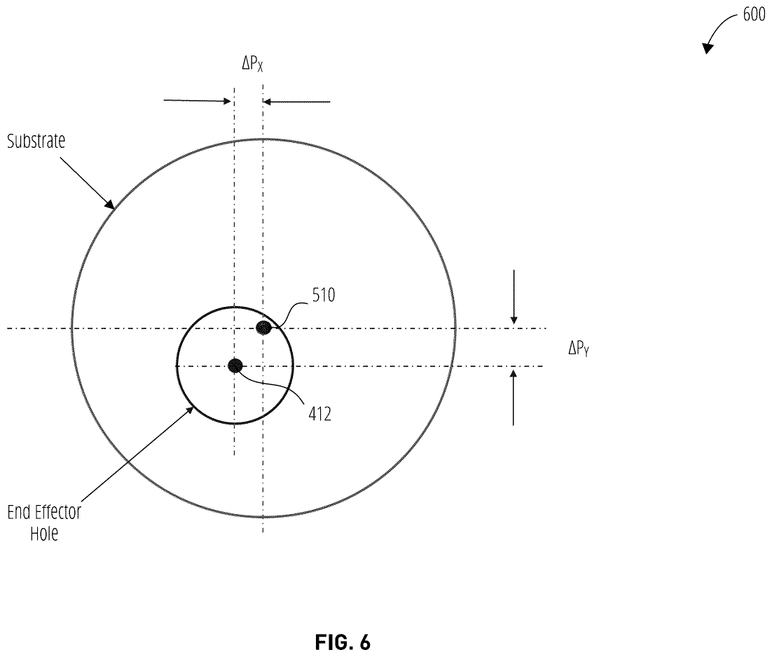

FIG. 6 illustrates a comparison 600 of the estimated calibration point 412 and the estimated center point 510 of the substrate 502, according to one embodiment. The illustrated comparison 600 may provide a top-down view of the end effector 404 loaded with a substrate 502 (i.e., the loaded end effector 500), where the calibration point 412 is the center of the hole 402 of the end effector 404, and the center point 510 is the center of a substrate 502 loaded onto the end effector 404. In some embodiments, the comparison 600 may include two different variables: ΔPₓ, which may represent a position offset of the center point 510 with respect to the calibration point 412 in a first direction (e.g., x-axis), and ΔP_{y}, which may represent a position offset of the center point 510 with respect to the calibration point 412 in a second direction orthogonal to the first direction (e.g., y-axis). The comparison 600 may also include a distance offset between the calibration point 412 and the center point 510, which may be described as d=\sqrt{ΔPₓ²+ΔP_{y}²}.

According to embodiments, the positioning of the center point 510 with respect to the calibration point 412 may be subject to one or more tolerance thresholds. For example, in order for the positioning of the center point 510 with respect to the calibration point 412 to satisfy tolerance requirements, ΔPₓ may be less than (or equal to) a first tolerance threshold, and ΔP_{y} may be less than (or equal to) a second tolerance threshold. In one embodiment, these first and second tolerance thresholds may be a same threshold. In other embodiments, these first and second tolerance thresholds may be different thresholds. In some embodiments, in order to satisfy tolerance requirements, the distance offset between the calibration point 412 and center point 510 may be less than (or equal to) a third threshold.

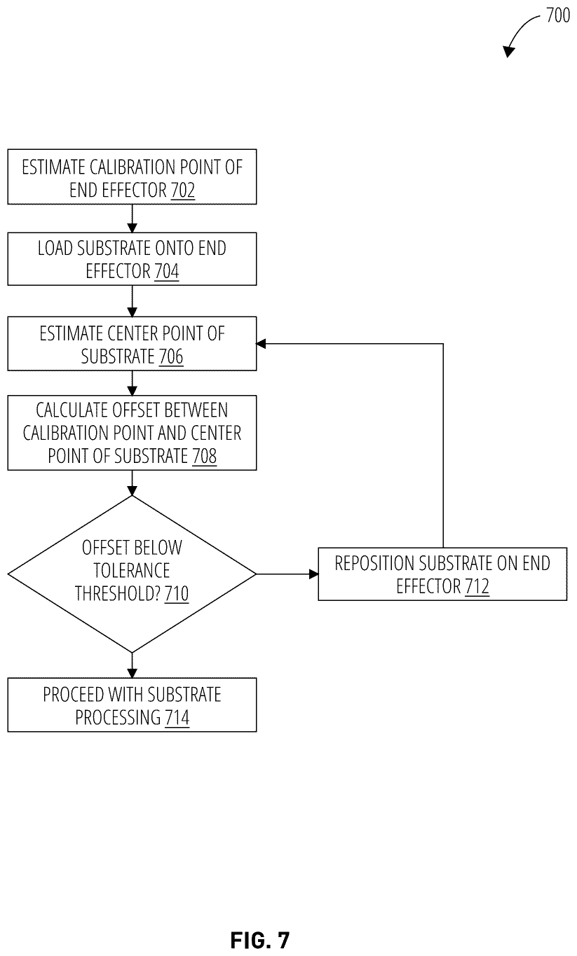

FIG. 7 illustrates a method 700 of automating a center-finding process of a substrate processing system, according to one embodiment. The method 700 may be performed by processing logic that may comprise hardware (e.g., circuitry, dedicated logic, programmable logic, microcode, etc.), software (e.g., instructions run on a processing device to perform hardware simulation), firmware, or a combination thereof. This processing logic may control operations of an end effector, such as the end effector 108 or end effector 404, and may receive sensor output data from at least one sensor, such as a through-beam sensor. In some embodiments, the method 700 may be performed by a controller, such as the controller 150, the controller 228 or the controller 272 as described above with respect to FIG. 1, FIG. 2A, and FIG. 2B, respectively. The method 700 can be controlled at least partially by other devices, such as a cloud database or processor having one or more processing devices.

At block 702, the processing logic may estimate a calibration point of an end effector. This calibration point may be the same or similar to the calibration point 412. The estimation of this calibration point may be the same or similar to what is described above with respect to FIG. 4. For example, two passes along different paths may be performed in order to determine at least three different reference points 406 corresponding to different physical locations of sidewall(s) of the hole 402 formed by the unloaded end effector 400 that may be used to estimate the center of the hole 402. The center of the hole 402 may be the calibration point 412. The calibration of the end effector may be estimated before a substrate is loaded onto the end effector.

At block 704, the processing logic may cause that a substrate be loaded onto the end effector.

At block 706, once the end effector is loaded with the substrate, the processing logic may estimate a center point of the substrate. This center point may be the same or similar to the center point 510. The estimation of the center point may be the same or similar to what is described above with respect to FIG. 5. For example, two passes along different paths may be performed in order to determine at least three different reference points 508 corresponding to different physical locations along the edge of the substrate 502. These reference points 508 may be used to estimate the center point 510 of the substrate 502.

At block 708, the processing logic may calculate one or more offset values between the calibration point and the center point of the substrate. These offset values may be as described above with respect to FIG. 6 (e.g., ΔPₓ, ΔP_{y}, and/or the distance offset).

At decision block 710, the processing logic may determine whether these one or more offset values satisfy corresponding tolerance thresholds. For example, the processing logic may determine whether ΔPₓ is less than (or equal to) a first tolerance threshold, ΔP_{y} is less than (or equal to) a second tolerance threshold, and/or whether the distance offset between the calibration point 412 and center point 510 is less than (or equal to) a third threshold. If the one or more offset values satisfies their corresponding tolerance thresholds, the processing logic may proceed with one or more subsequent substrate processing processes at block 714, such as load lock chamber calibration. However, if at least one of the corresponding tolerance thresholds are not satisfied, the substrate may be repositioned on the end effector to compensate for the offset between the center point of the wafer and the calibration point at block 712.

This repositioning of the substrate may be performed in various ways that each provide the same outcome: smaller offsets between the center point of the substrate and the calibration point of the end effector. In one embodiment, the end effector offloads the substrate in the same manner that the end effector loaded the substrate, and then reloads the substrate after compensating for the calculated offsets between the center point of the substrate and the calibration point of the end effector. In another embodiment, the calculated offsets are compensated for before the substrate is offloaded from the end effector, and then the end effector reloads the substrate in the same manner that the end effector originally loaded the substrate.

Once the substrate has been repositioned on the end effector, the operations of block 706 are again performed in order to estimate an updated center point of the substrate. This updated center point is then compared against the calibration point. If offsets between the updated center point and the calibration point satisfy the respective tolerance threshold(s), then the processing logic may move on to subsequent substrate processing processes at block 714. If not, the repositioning of the substrate with respect to the calibration point may be repeated until the respective tolerance threshold(s) are satisfied.

In some embodiments, the substrate may not be repositioned with respect to the calibration point at all. Instead, in these embodiments, Once the processing logic determines the one or more offset values, the processing logic may store these one or more offsets to be used by one or more future calibration processes or substrate processing processes. During these subsequent calibration or substrate processing processes, these one or more offset values may be referenced to adjust the wafer's position in real time or otherwise compensate for the misalignment. In other words, the one or more offsets may be incorporated into one or more future processes that use the substrate without repositioning the substrate on the end effector. By doing so, the processing logic can avoid physically removing and reloading the substrate onto the end effector and save time and resources.

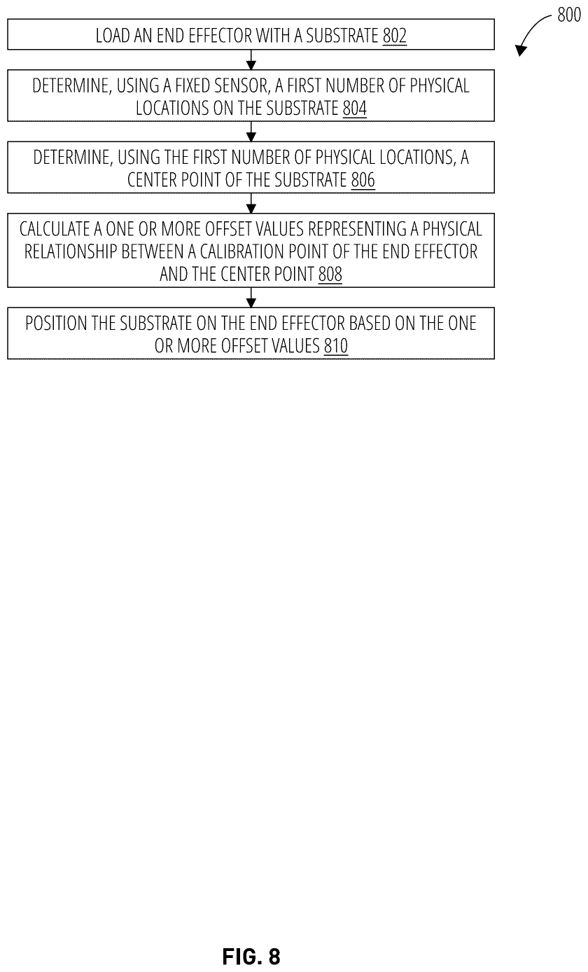

FIG. 8 is a flowchart illustrating a method 800 of aligning a center point of a substrate with a calibration point on an end effector, according to one embodiment. The method 800 may be performed by processing logic that may comprise hardware (e.g., circuitry, dedicated logic, programmable logic, microcode, etc.), software (e.g., instructions run on a processing device to perform hardware simulation), firmware, or a combination thereof. This processing logic may control operations of an end effector, such as the end effector 108 or end effector 404, and may receive sensor output data from at least one sensor, such as a through-beam sensor. In some embodiments, the method 800 may be performed by a controller, such as the controller 150, the controller 228 or the controller 272 as described above with respect to FIG. 1, FIG. 2A, and FIG. 2B, respectively. The method 800 can be controlled at least partially by other devices, such as a cloud database or processor having one or more processing devices.

At block 802, the processing logic may load an end effector with a substrate.

At block 804, the processing logic may determine a first number of physical locations on the substrate using a fixed sensor. This fixed sensor may be a through-beam optical sensor (also referred to as through-beam sensor). In some embodiments, determining this first number of physical locations may include determining a first physical location on the substrate and a second physical location on the substrate by moving the substrate along a first path with respect to the fixed sensor. These first and second physical locations may be different physical locations. In some embodiments, each of these first and second physical locations may correspond with a different portion of an edge of the substrate. According to embodiments, a third physical location on the substrate and a fourth physical location on the substrate may be determined by moving the substrate along a second path with respect to the fixed sensor. This second path may be different from the first path. The third and fourth physical locations may be different from the first and second physical locations, respectively, and may be different from each other. Each of these third and fourth physical locations may correspond with a different portion of the edge of the substrate than the first and second physical locations. Each of these first, second, third, and fourth physical locations may be referred to as reference points 508 above with respect to FIG. 5.

In at least some embodiments, the processing logic may use robot arm positions corresponding to transitions of the output of the fixed sensor. These transitions may correspond to the different physical locations described above. The processing logic may determine the physical locations on the substrate using the robot arm positions as described herein.

According to embodiments, an end effector (or a substrate loaded onto it) can be moved along two different paths by leveraging linear or radial motion, actuation mechanisms, or a combination thereof. The below example described how two passes having different paths may be achieved by leveraging movement around a rotational axis. First, the end effector may be set to a first radial distance from the rotational axis or links of the robot 106 may be oriented such that the arm of the robot has a first length. Then, by rotating the robot arm via the rotational axis, the end effector and/or the substrate moves along a first path corresponding to that first radial distance. Then, the end effector may be set to a second radial distance from the rotational axis or links of the robot 106 may be oriented such that the robot arm has a second length different from the first length. This may be achieved by “pushing” or “pulling” the robot arm using one or more actuators or by adjusting the respective orientation of the links of the robot 106. Then, the end effector and/or the substrate can move along a second path corresponding to that second radial distance.

At block 806, the processing logic may determine a center point of the substrate using the first number of physical locations. This may be performed as described above with respect to estimating the center point 510 of the substrate 502 as described in FIG. 5.

At block 808, the processing logic may calculate one or more offset values representing a physical relationship between a calibration point of the end effector and the center point. These offset values may be calculated or otherwise determined as described above with respect to FIG. 6.

At block 810, the processing logic may position the substrate on the end effector based on the one or more offset values. This may be performed as described above with respect to the positioning or repositioning of the center point of the substrate to the calibration point as described in FIG. 7.

In various embodiments, before loading the end effector with a substrate, the processing logic may determine a second number of physical locations on the end effector using the fixed sensor. These second number of physical locations may be used to determine the calibration point. Determining these second number of physical locations may include determining a first physical location on the end effector and a second physical location on the end effector by moving the end effector along a first path with respect to the fixed sensor. These first and second physical locations may be different physical locations. In some embodiments, each of these first and second physical locations may correspond with a different portion of sidewall(s) of a hole formed by the end effector. The calibration point may be the center of this hole formed by the end effector. According to embodiments, a third physical location on the end effector and a fourth physical location on the end effector may be determined by moving the end effector along a second path with respect to the fixed sensor. This second path may be different from the first path. The third and fourth physical locations may be different from the first and second physical locations, respectively, and may be different from each other. Each of these third and fourth physical locations may correspond with a different portion of the sidewall(s) of the hole formed by the end effector. Each of these first, second, third, and fourth physical locations may be referred to as reference points 406 above with respect to FIG. 4.

According to embodiments, after positioning the substrate on the end effector based on the one or more offset values, the processing logic may determine a third number of physical locations on the substrate using the fixed sensor. The third number of physical locations may be used to determine an updated center point of the substrate (i.e., the position of the center point after the substrate is repositioned on the end effector). The processing logic may then calculate one or more second offset values representing a physical relationship between the calibration point and the updated center point. If these second offset values do not satisfy a tolerance threshold (or respective tolerance thresholds), then the substrate is repositioned on the end effector based on the one or more second offset values. However, if these second offset values do satisfy the tolerance threshold (or respective tolerance thresholds), the processing logic may calibrate one or more through-beam sensors of a load-lock chamber using the end effector loaded with the substrate.

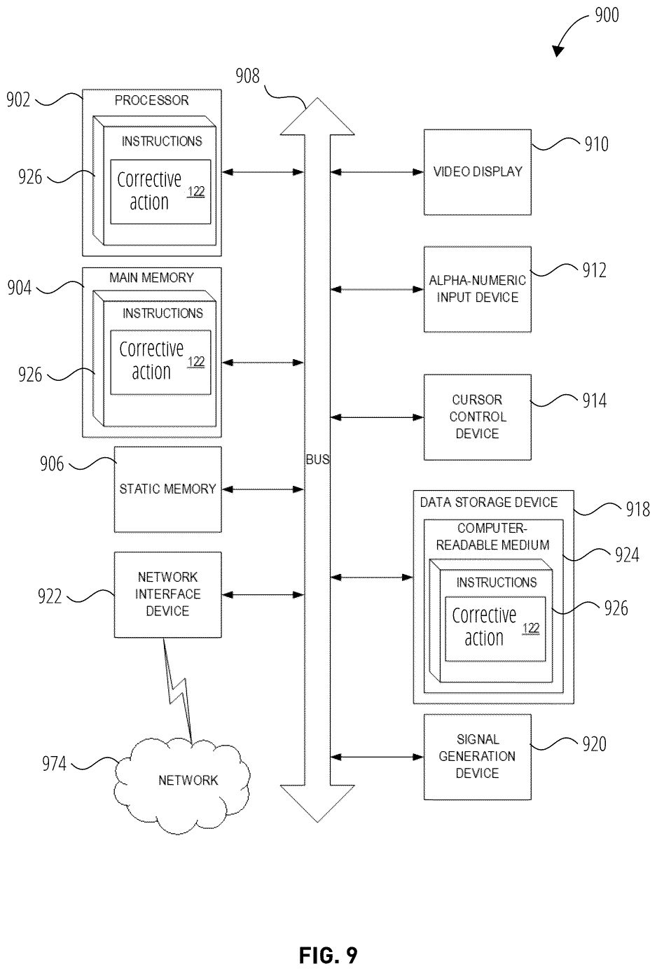

FIG. 9 is a block diagram illustrating a computer system 900, according to certain embodiments. In some embodiments, computer system 900 may be connected (e.g., via a network, such as a Local Area Network (LAN), an intranet, an extranet, or the Internet) to other computer systems. Computer system 900 may operate in the capacity of a server or a client computer in a client-server environment, or as a peer computer in a peer-to-peer or distributed network environment. Computer system 900 may be provided by a personal computer (PC), a tablet PC, a Set-Top Box (STB), a Personal Digital Assistant (PDA), a cellular telephone, a web appliance, a server, a network router, switch or bridge, or any device capable of executing a set of instructions (sequential or otherwise) that specify actions to be taken by that device. Further, the term “computer” shall include any collection of computers that individually or jointly execute a set (or multiple sets) of instructions to perform any one or more of the methods described herein. In one embodiment, the computer system 900 may represent one or more portions of the processing system 100 as described above in FIG. 1. The computer system 900 may perform some or all operations corresponding to aligning a center point of a substrate to a calibration point of an end effector as described herein.

In a further aspect, the computer system 900 may include a processing device 902, a volatile memory 904 (e.g., Random Access Memory (RAM)), a non-volatile memory 906 (e.g., Read-Only Memory (ROM) or Electrically-Erasable Programmable ROM (EEPROM)), and a data storage device 918, which may communicate with each other via a bus 908. In some embodiments, the processor 902 may perform some or all of the operations corresponding to the method 700 of FIG. 7 or the method 800 of FIG. 8. The processor 902 may perform one or more of the operations to align the center point of a substrate to a calibration point of the end effector as described herein.

Processing device 902 may be provided by one or more processors such as a general purpose processor (such as, for example, a Complex Instruction Set Computing (CISC) microprocessor, a Reduced Instruction Set Computing (RISC) microprocessor, a Very Long Instruction Word (VLIW) microprocessor, a microprocessor implementing other types of instruction sets, or a microprocessor implementing a combination of types of instruction sets) or a specialized processor (such as, for example, an Application Specific Integrated Circuit (ASIC), a Field Programmable Gate Array (FPGA), a Digital Signal Processor (DSP), or a network processor).

Computer system 900 may further include a network interface device 922 (e.g., coupled to network 974). Computer system 900 also may include a video display unit 910 (e.g., an LCD), an alphanumeric input device 912 (e.g., a keyboard), a cursor control device 914 (e.g., a mouse), and a signal generation device 920.

In some embodiments, data storage device 918 may include a non-transitory computer-readable storage medium 924 (e.g., non-transitory machine-readable medium) on which may store instructions 926 encoding any one or more of the methods or functions described herein.

Instructions 926 may also reside, completely or partially, within volatile memory 904 and/or within processing device 902 during execution thereof by computer system 900, hence, volatile memory 904 and processing device 902 may also constitute machine-readable storage media.

While computer-readable storage medium 924 is shown in the illustrative examples as a single medium, the term “computer-readable storage medium” shall include a single medium or multiple media (e.g., a centralized or distributed database, and/or associated caches and servers) that store the one or more sets of executable instructions. The term “computer-readable storage medium” shall also include any tangible medium that is capable of storing or encoding a set of instructions for execution by a computer that cause the computer to perform any one or more of the methods described herein. The term “computer-readable storage medium” shall include, but not be limited to, solid-state memories, optical media, and magnetic media.

The methods, components, and features described herein may be implemented by discrete hardware components or may be integrated in the functionality of other hardware components such as ASICS, FPGAs, DSPs or similar devices. In addition, the methods, components, and features may be implemented by firmware modules or functional circuitry within hardware devices. Further, the methods, components, and features may be implemented in any combination of hardware devices and computer program components, or in computer programs.

Unless specifically stated otherwise, terms such as “receiving,” “performing,” “providing,” “obtaining,” “causing,” “accessing,” “determining,” “adding,” “using,” “training,” “reducing,” “generating,” “correcting,” or the like, refer to actions and processes performed or implemented by computer systems that manipulates and transforms data represented as physical (electronic) quantities within the computer system registers and memories into other data similarly represented as physical quantities within the computer system memories or registers or other such information storage, transmission or display devices. Also, the terms “first,” “second,” “third,” “fourth,” etc. as used herein are meant as labels to distinguish among different elements and may not have an ordinal meaning according to their numerical designation.

Examples described herein also relate to an apparatus for performing the methods described herein. This apparatus may be specially constructed for performing the methods described herein, or it may include a general purpose computer system selectively programmed by a computer program stored in the computer system. Such a computer program may be stored in a computer-readable tangible storage medium.

The methods and illustrative examples described herein are not inherently related to any particular computer or other apparatus. Various general purpose systems may be used in accordance with the teachings described herein, or it may prove convenient to construct more specialized apparatus to perform methods described herein and/or each of their individual functions, routines, subroutines, or operations. Examples of the structure for a variety of these systems are set forth in the description above.

The above description is intended to be illustrative, and not restrictive. Although the present disclosure has been described with references to specific illustrative examples and embodiments, it will be recognized that the present disclosure is not limited to the examples and embodiments described. The scope of the disclosure should be determined with reference to the following claims, along with the full scope of equivalents to which the claims are entitled.

What is claimed is:

1. A method comprising:
loading a substrate onto an end effector;
determining, using a fixed sensor, first robot arm positions for a first number of physical locations on the substrate;
determining, using the first robot arm positions for the first number of physical locations, a center point of the substrate;
calculating one or more offset values representing a physical relationship between a calibration point of the end effector and the center point; and
positioning the substrate on the end effector based on the one or more offset values.

2. The method of claim 1, wherein determining the first robot arm positions for the first number of physical locations comprises:
determining a first robot arm position of the first robot arm positions corresponding to a first physical location on the substrate and a second robot arm position of the first robot arm positions corresponding to a second physical location on the substrate by moving the substrate along a first path with respect to the fixed sensor, wherein the first physical location is different from the second physical location; and
determining a third robot arm position of the first robot arm positions corresponding to a third physical location on the substrate and a fourth robot arm position of the first robot arm positions corresponding to a fourth physical location on the substrate by moving the substrate along a second path with respect to the fixed sensor, wherein the second path is different from the first path, wherein the third physical location is different from the first and second physical locations, and wherein the fourth physical location is different from the first, second, and third physical locations.

3. The method of claim 1, further comprising, before loading the end effector with the substrate:
determining, using the fixed sensor, second robot arm positions for a second number of physical locations on the end effector; and
determining the calibration point using the second robot arm positions for the second number of physical locations.

4. The method of claim 3, wherein determining the second number of physical locations comprises:
determining a first robot arm position of the second robot arm positions corresponding to a first physical location on the end effector and a second robot arm position of the second robot arm positions corresponding to a second physical location on the end effector by moving the end effector along a first path with respect to the fixed sensor, wherein the first physical location is different from the second physical location; and
determining a third robot arm position of the second robot arm positions corresponding to a third physical location on the end effector and a fourth robot arm position of the second robot arm positions corresponding to a fourth physical location on the end effector by moving the end effector along a second path with respect to the fixed sensor, wherein the second path is different from the first path, wherein the third physical location is different from the first and second physical locations, and wherein the fourth physical location is different from the first, second, and third physical locations.

5. The method of claim 4, wherein the calibration point is a center of a hole formed by the end effector, and wherein the first, second, third, and fourth physical locations are different locations on one or more side walls of the hole.

6. The method of claim 1, further comprising, after positioning the substrate on the end effector based on the one or more offset values:
determining, using the fixed sensor, third robot arm positions for a third number of physical locations on the substrate;
determining, using the third robot arm positions for the third number of physical locations, an updated center point of the substrate;
calculating one or more second offset values representing a physical relationship between the calibration point and the updated center point;
determining that one or more of the one or more second offset values do not satisfy a tolerance threshold; and
positioning the substrate on the end effector based on the one or more second offset values.

7. The method of claim 1, further comprising, after positioning the substrate on the end effector based on the one or more offset values:
determining, using the fixed sensor, third robot arm positions for a third number of physical locations on the substrate;
determining, using the third robot arm positions for the third number of physical locations, an updated center point of the substrate;
calculating one or more second offset values representing a physical relationship between the calibration point and the updated center point;
determining that each of the one or more second offset values satisfies a tolerance threshold; and
calibrating one or more through-beam sensors of a load lock chamber using the end effector loaded with the substrate.

8. The method of claim 1, wherein positioning the substrate on the end effector comprises:
offloading the substrate from the end effector; and
after adjusting the end effector to compensate for the one or more offset values, reloading the substrate onto the end effector.

9. The method of claim 1, wherein positioning the substrate on the end effector comprises:
after adjusting the end effector to compensate for the one or more offset values, offloading the substrate from the end effector; and
reloading the substrate onto the end effector.

10. The method of claim 1, wherein the fixed sensor is a through-beam sensor.

11. A device comprising:
one or more processors; and
a memory storing instructions that, when executed by the one or more processors, cause the device to:
load a substrate onto an end effector;
determine, using a fixed sensor, first robot arm positions for a first number of physical locations on the substrate;
determine, using the first arm positions for the first number for the first number of physical locations, a center point of the substrate;
calculate one or more offset values representing a physical relationship between a calibration point of the end effector and the center point; and
position the substrate on the end effector based on the one or more offset values.

12. The device of claim 11, wherein to determine the first robot arm positions for the first number of physical locations, the instructions cause the device to:
determine a first robot arm position of the first robot arm positions corresponding to a first physical location on the substrate and second robot arm position of the first robot arm positions corresponding to a second physical location on the substrate by moving the substrate along a first path with respect to the fixed sensor, wherein the first physical location is different from the second physical location; and
determine third robot arm position of the first robot arm positions corresponding to a third physical location on the substrate and a fourth robot arm position of the first robot arm positions corresponding to a fourth physical location on the substrate by moving the substrate along a second path with respect to the fixed sensor, wherein the second path is different from the first path, wherein the third physical location is different from the first and second physical locations, and wherein the fourth physical location is different from the first, second, and third physical locations.

13. The device of claim 11, wherein, before loading the end effector with the substrate, the instructions further cause the device to:
determine, using the fixed sensor, second robot arm positions for a second number of physical locations on the end effector; and
determine, using the second robot arm positions for the second number of physical locations, the calibration point.

14. The device of claim 13, wherein to determine the second number of physical locations, the instructions cause the device to:
determine a first robot arm position of the second robot arm positions corresponding to a first physical location on the end effector and a second robot arm position of the second robot arm positions corresponding to a second physical location on the end effector by moving the end effector along a first path with respect to the fixed sensor, wherein the first physical location is different from the second physical location; and
determine a third robot arm position of the second robot arm positions corresponding to a third physical location on the end effector and a fourth robot arm position of the second robot arm positions corresponding to a fourth physical location on the end effector by moving the end effector along a second path with respect to the fixed sensor, wherein the second path is different from the first path, wherein the third physical location is different from the first and second physical locations, and wherein the fourth physical location is different from the first, second, and third physical locations.

15. The device of claim 14, wherein the calibration point is a center of a hole formed by the end effector, and wherein the first, second, third, and fourth physical locations are different locations on one or more side walls of the hole.

16. A substrate processing system comprising:
a robotic arm comprising a plurality of links that rotate along one or more rotational axis and an end effector, where an end effector of the robotic arm is capable of moving rotationally or linearly; and
one or more through-beam sensors each configured to detect when the robotic arm or a substrate is within a respective field of view (FOV);
one or more processors; and
a memory storing instructions that, when executed by the one or more processors, cause the substrate processing system to:
load a substrate onto the end effector;
determine, using the one or more through-beam sensors, a first number of robot arm positions for a first number of physical locations on the substrate;
determine, using the first number of robot arm positions for the first number of physical locations, a center point of the substrate;
calculate one or more offset values representing a physical relationship between a calibration point of the end effector and the center point; and
compensate for the one or more offset values in one or more subsequent calibration processes.

17. The substrate processing system of claim 16, wherein to determine the first robot arm positions for the first number of physical locations, the instructions cause the substrate processing system to:
determine a first robot arm position of the first robot arm positions corresponding to a first physical location on the substrate and a second robot arm position of the first robot arm positions corresponding to a second physical location on the substrate by moving the substrate along a first path with respect to the one or more through-beam sensors, wherein the first physical location is different from the second physical location; and
determine a third robot arm position of the first robot arm positions corresponding to a third physical location on the substrate and a fourth robot arm position of the first robot arm positions corresponding to a fourth physical location on the substrate by moving the substrate along a second path with respect to the one or more through-beam sensors, wherein the second path is different from the first path, wherein the third physical location is different from the first and second physical locations, and wherein the fourth physical location is different from the first, second, and third physical locations.

18. The substrate processing system of claim 16, wherein, before loading the end effector with the substrate, the instructions further cause the substrate processing system to:
determine, using the one or more through-beam sensors, second robot arm positions for a second number of physical locations on the end effector; and
determine, using the second robot arm positions for the second number of physical locations, the calibration point.

19. The substrate processing system of claim 18, wherein to determine the second number of physical locations, the instructions cause the substrate processing system to:
determine a first robot arm position of the second robot arm positions corresponding to a first physical location on the end effector and a second robot arm position of the second robot arm positions corresponding to a second physical location on the end effector by moving the end effector along a first path with respect to the through-beam sensor, wherein the first physical location is different from the second physical location; and
determine a third robot arm position of the second robot arm positions corresponding to a third physical location on the end effector and a fourth robot arm position of the second robot arm positions corresponding to a fourth physical location on the end effector by moving the end effector along a second path with respect to the through-beam sensor, wherein the second path is different from the first path, wherein the third physical location is different from the first and second physical locations, and wherein the fourth physical location is different from the first, second, and third physical locations.

20. The substrate processing system of claim 19, wherein the calibration point is a center of a hole formed by the end effector, and wherein the first, second, third, and fourth physical locations are different locations on one or more side walls of the hole.
